(19) United States
(12) Patent Application Publication
(10) Pub. No.: US 2025/0101576 A1
(43) Pub. Date: Mar. 27, 2025

(54) METHOD FOR DEPOSITING A STRAIN RELAXED GRADED BUFFER LAYER OF SILICON GERMANIUM ON A SURFACE OF A SUBSTRATE

(71) Applicant: SILTRONIC AG, Munich (DE)

(72) Inventors: Lucas BECKER, Simbach (DE); Peter STORCK, Burghausen (DE)

(21) Appl. No.: 18/833,949

(22) PCT Filed: Dec. 14, 2022
(86) PCT No.: PCT/EP2022/085871

§ 371 Date: Jul. 29, 2024

(30) Foreign Application Priority Data
Jan. 31, 2022 (EP) 22154292

(51) Int. Cl. C23C 16/14; C30B 29/06; C30B 33/00

(52) U.S. Cl. CPC C23C 16/14; C30B 29/06; C30B 33/00

(57) ABSTRACT

A method deposits a strain relaxed graded buffer layer of silicon germanium on a surface of a substrate. The surface includes silicon, and the buffer layer has an increasing content of germanium up to a final content. The method includes: conducting GeCl₄ and SiH₂Cl₂ during a first stage and a second stage over the surface of the substrate at a deposition temperature of not less than 800° C.; growing the buffer layer with a grade rate that is less than 10% Ge/μm; and growing the buffer layer with a growth rate that is not less than 0.1 μm/min during the first stage, and that is less than 0.1 μm/min during the second stage.

### CROSS REFERENCE TO RELATED APPLICATIONS

This application is a U.S. National Phase application under 35 U.S.C. § 371 of International Application No. PCT/EP2022/085871, filed on Dec. 14, 2022, and claims benefit to European Patent Application No. EP22154292, filed on Jan. 31, 2022. The International Application was published in English on Aug. 3, 2023 as WO 2023/143804 A1 under PCT Article 21 (2).

### FIELD

The present disclosure is directed to a method for depositing a strain relaxed graded buffer layer of silicon germanium on a surface of a substrate.

### BACKGROUND

Silicon germanium (or briefly SiGe) is a semiconductor comprising both silicon and germanium according to the formula Si₁₋ₓGeₓ, wherein 0<x<1. Accordingly, a germanium content of 25% Ge is represented by the formula Si_{0.75}Ge_{0.25}.

Due to lattice mismatch between silicon and silicon germanium, a heteroepitaxia Si₁₋ₓGeₓ buffer layer grows strained on a Si substrate up to a critical thickness, where the strain energy becomes high enough, that it is favorable to form misfit dislocations (and their respective threading dislocation segment, that penetrate the surface of the layer) that relax the epitaxial layer and reduce strain. Relaxed SiGe buffer layers may be used to deposit strained silicon thereon for manufacturing electronic devices having improved properties. The quality of relaxed SiGe buffer layers is largely determined by the Threading Dislocation Density (TDD).

WO 2004 084 268 A2 and US 2007 0 077 734 A1, each disclose a method for depositing an epitaxial germanium-containing layer on a silicon single crystal structure.

US 2015 0 318 355 A1 discloses the manufacturing of a strain-relieved buffer comprising a first and a second SiGe layer, wherein a TDD of the second SiGe layer is less than 1×10³/cm².

### SUMMARY

In an embodiment, the present disclosure provides a method that deposits a strain relaxed graded buffer layer of silicon germanium on a surface of a substrate. The surface includes silicon, and the buffer layer has an increasing content of germanium up to a final content. The method includes: conducting GeCl4 and SiH2Cl2 during a first stage and a second stage over the surface of the substrate at a deposition temperature of not less than 800° C.; growing the buffer layer with a grade rate that is less than 10% Ge/μm; and growing the buffer layer with a growth rate that is not less than 0.1 μm/min during the first stage, and that is less than 0.1 μm/min during the second stage.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 schematically depicts the sample configuration used in a first set of experiments;

FIG. 2 depicts the results of the first set of experiments;

FIG. 3 schematically depicts the sample configuration used in a second set of experiments;

FIG. 4 depicts the results of the second set of experiments; and

FIG. 5 depicts the results of an example.

### DETAILED DESCRIPTION

The present disclosure is directed to depositing a strain relaxed graded buffer layer of silicon germanium on a surface of a substrate, where the surface consists of silicon and the buffer layer has an increasing content of germanium up to a final content.

Aspects of the present disclosure provide a method for depositing a strain relaxed graded buffer layer of silicon germanium on a surface of a substrate that is comparatively easy to perform and that provides access to a TDD, which is comparatively low.

In one aspect of the present disclosure, a method is provided for depositing a strain relaxed graded buffer layer of silicon germanium on a surface of a substrate, the surface consisting of silicon and the buffer layer having an increasing content of germanium up to a final content. The method includes: conducting GeCl₄ and SiH₂Cl₂ during a first and a second stage over the surface of the substrate at a deposition temperature of not less than 800° C.; growing the buffer layer with a grade rate that is less than 10% Ge/μm; and growing the buffer layer with a growth rate that is not less than 0.1 μm/min during the first stage and that is less than 0.1 μm/min during the second stage.

The following considerations and findings help to understand the present disclosure.

Relaxation by misfit dislocations can be achieved by two mechanisms, which influence the final TDD in a different way:
(i) nucleation and glide of new dislocation loops; each new loop generates 2 threading dislocations, which increase the final TDD.
(ii) glide and elongation of existing dislocation loops; pre-existing loops glide and relax the buffer layer, the TDD is not increased.

A SiGe buffer layer with low TDD has a low number of half-loops that glided far within the buffer layer forming long misfit dislocation segments, whereas a buffer layer with high TDD has a high number of half-loops that have only short misfit dislocation segments. The final TDD thus is a result of the balance between (i) and (ii), namely how many half-loops are generated and how long those are able to glide unhindered.

The balance of the two mechanisms (i) and (ii) is of differing importance in different phases of the buffer layer growth. In the early stage of the buffer layer growth no dislocations are present within the buffer layer, new loops have to be nucleated to relax the buffer layer, thus (i) is the dominating mechanism. During continued grading it is preferred that (ii) is the dominating mechanism to receive a low TDD.

Accordingly, the growth conditions employed during the two phases of buffer growth have to be optimized individually, which is a core insight of this present disclosure. Different growth rates are used in different stages of buffer layer growth to generate a low final TDD of the relaxed buffer layer.

During a first stage of the deposition of the SiGe buffer layer, the growth rate is not less than 0.1 μm/min, whereas the growth rate is less than 0.1 μm/min during a second stage. Preferably, the growth rate is not less than 0.3 μm/min and not more than 0.6 μm/min during the first stage and not less than 0.01 μm/min and not more than 0.095 μm/min during the second stage.

The grade rate in terms of increase of content of germanium per thickness of the buffer layer is less than 10% Ge/μm during both the first and the second stage of the deposition process.

The higher growth rate during the first stage ensures optimum conditions in the nucleation phase of the relaxation process, which results in a low base TDD. This TDD is kept low during continued grading by employing a very low growth rate and grading rate in the second stage.

Preferably, the first stage ends not later than when about ⅓ of the final content of Ge has been reached. The second stage ends when the final content of Ge has been reached.

According to an embodiment of the present disclosure, the germanium final content is not less than 2% Ge and not more than 90% Ge. According to a preferred embodiment, the final content is 25% Ge and the first stage ends when a content of 8% Ge has been reached.

The SiGe buffer layer is grown by using a CVD method (chemical vapor deposition) with GeCl₄ and SiH₂Cl₂ as precursor gases and at a deposition temperature that is not less than 800° C.

Preferably, the SiGe buffer layer is deposited on the surface of a silicon single crystal wafer or a SOI wafer (silicon on insulator).

The present disclosure is further explained by referring to figures and examples.

### EXAMPLE

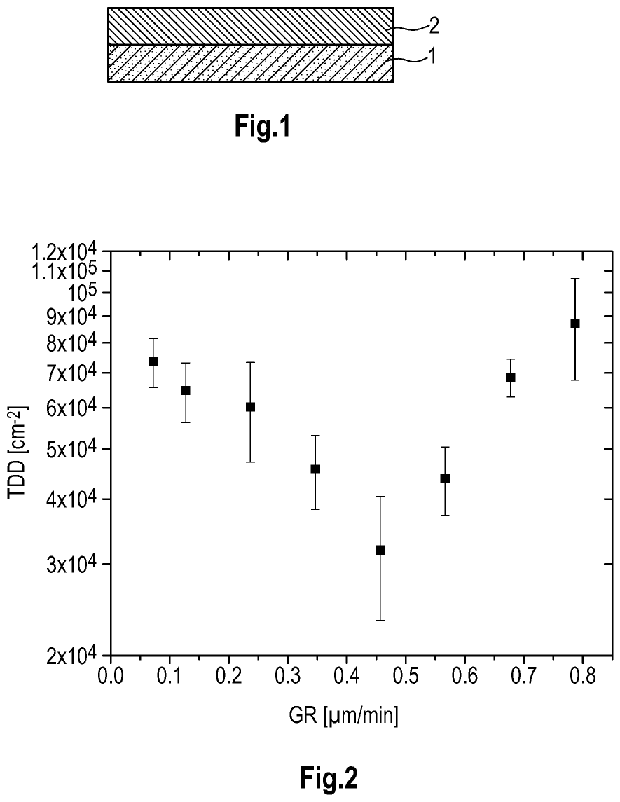

The growth rate influence on TDD in a first stage of buffer growth (nucleation phase) has been examined in a first set of experiments. The sample configuration used in the first set of experiments is depicted in FIG. 1.

A graded SiGe buffer layer 2 to a final concentration of 8% Ge was grown on a silicon single crystal wafer 1 (FIG. 1). The growth rate was varied from 0.05 μm/min to 0.8 μm/min and a grading rate of 4% Ge/μm has been used. The resulting TDD has been measured after defect selective etching. As shown in FIG. 2, which displays the TDD over the growth rate GR, the TDD decreases with increasing growth rate to a minimum at 0.46 μm/min.

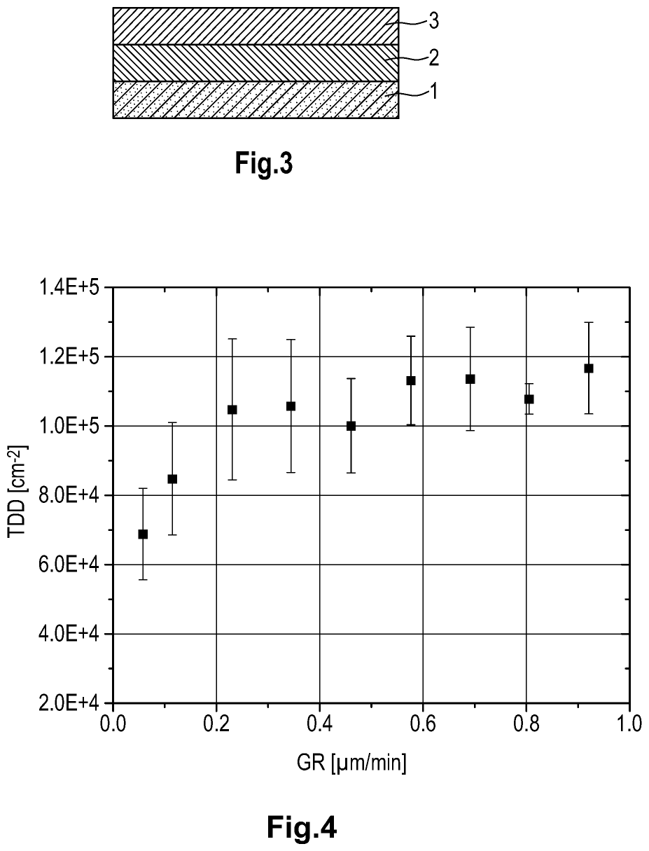

The growth rate influence in second stage of buffer growth (grading phase) has been examined in a second set of experiments. The sample configuration used in the second set of experiments is depicted in FIG. 3.

On top of a first SiGe buffer layer 2 with a Ge-concentration of 8%, a second graded buffer layer 3 was grown to a final concentration of 16% Ge. A grading rate of 4% Ge/μm has been used. The growth rate of the second layer 2 has been varied from 0.05 μm/min to 0.95 μm/min. From 0.05 μm/min to 0.23 μm/min the TDD increases, at higher growth rates the TDD stays constant. As shown in FIG. 4, the lowest TDD is realized at lower growth rates.

A full strain relaxed graded buffer layer up to a germanium content of 25% Ge has been deposited on a silicon single crystal wafer in accordance with the present disclosure (example).

During the first stage of the deposition process, i.e. from the beginning of the process until a germanium content of 8% Ge has been reached, the growth rate was 0.46 μm/min in accordance with the results of the first set of experiments and in order to generate a low base TDD within the base layer. For further grading up to the final content of 25% Ge the growth rate was 0.05 μm/min in accordance with the results of the second set of experiments. The overall grading rate was 2.1% Ge/μm.

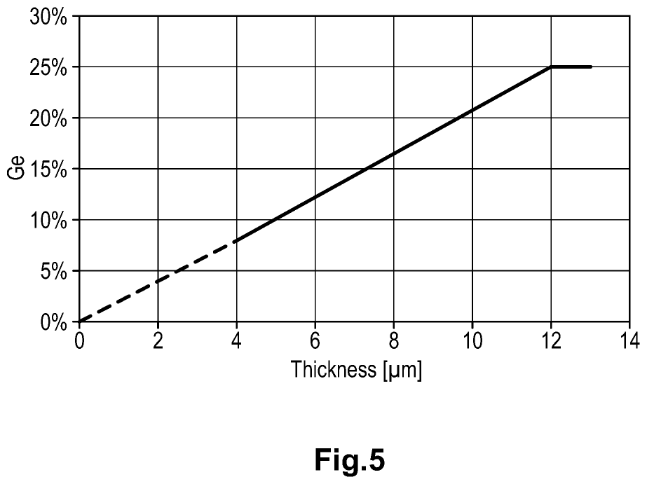

As shown in FIG. 5 which depicts the content of germanium in the grown buffer layer over the thickness of the grown buffer layer, the final TDD achieved was 4×10⁴/cm². The dotted line in FIG. 5 represents the first stage, the solid line the second stage of the deposition process.

The sets of experiments and the example have been performed in a commercial epitaxial reactor of type EPSILON 3200 manufactured by ASM at a deposition temperature of 1050° C. and with GeCl₄ and SiH₂Cl₂ as precursor gases.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### List of Reference Numerals Employed

1 substrate

2 first silicon germanium buffer layer grown with a first growth rate

3 second silicon germanium buffer layer grown with a second growth rate

1. A method for depositing a strain relaxed graded buffer layer of silicon germanium on a surface of a substrate, the surface comprising silicon and the buffer layer comprising an increasing content of germanium up to a final content, the method comprising:
conducting GeCl₄ and SiH₂Cl₂ during a first stage and a second stage over the surface of the substrate at a deposition temperature of not less than 800° C.;
growing the buffer layer with a grade rate that is less than 10% Ge/μm; and
growing the buffer layer with a growth rate that is not less than 0.1 μm/min during the first stage, and that is less than 0.1 μm/min during the second stage.

2. The method as claimed in claim 1, wherein the first stage ends not later than when ⅓ of the final content of germanium has been reached.

3. The method as claimed in claim 1, wherein the final content of germanium is not less than 2% Ge and not more than 90% Ge.

4. The method as claimed in claim 1, wherein the buffer layer is deposited by chemical vapor deposition.

5. The method as claimed in claim 1, wherein the buffer layer is grown on a silicon single crystal wafer or on a silicon on insulator wafer.

6. The method of claim 1 wherein the surface consists of silicon.
